(19) United States
(12) Patent Application Publication
(10) Pub. No.: US 2026/0344377 A1
(43) Pub. Date: Oct. 29, 2026

(54) SEMICONDUCTOR PACKAGE AND METHOD

(71) Applicant: Taiwan Semiconductor Manufacturing Co., Ltd., Hsincu (TW)

(72) Inventors: Jui Hsuan Tsai, Taipei City (TW); Chen-Chiang Yu, Taoyuan City (TW); Su-Chun Yang, Hsinchu (TW); Jih-Churng Twu, Hsinchu County (TW); Chung-Shi Liu, Hsinchu (TW); Chen-Hua Yu, Hsinchu (TW)

(21) Appl. No.: 19/732,470

(22) Filed: Jul. 6, 2026

Related U.S. Application Data
(63) Continuation of application No. 18/679,788, filed on May 31, 2024.

(51) Int. Cl. H10P 95/90; H10P 30/20; H10P 52/00; H10P 52/40; H10W 72/00; H10W 80/00; H10W 90/00

(52) U.S. Cl. CPC H10P 95/906; H10P 30/20; H10W 90/00; H10P 52/00; H10P 52/402; H10W 72/07331; H10W 80/327

(57) ABSTRACT

A semiconductor package and methods of forming the same are provided. The methods may include implanting a substrate with a dopant to form an implanted layer in the substrate, thinning the substrate, and heating the substrate to split the substrate at the implanted layer into a first portion and a second portion.

### CROSS-REFERENCE TO RELATED APPLICATIONS

This application is a continuation of U.S. patent application Ser. No. 18/679,788, filed on May 31, 2024, and entitled “Semiconductor Package and Method,” which application is incorporated herein by reference.

### BACKGROUND

Semiconductor wafers may be thinned in some manufacturing processes. The thinning process may be performed through Chemical Mechanical Polishing (CMP) processes or grinding processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 illustrate a cross-sectional views of semiconductor package components in accordance with some embodiments.

FIGS. 3, 4, 5, 6, and 7 illustrate cross-sectional views of intermediate steps of forming a semiconductor package in accordance with some embodiments.

FIG. 8 illustrates a process flow of forming the semiconductor package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A process of forming a semiconductor package including a wafer splitting process is provided. In accordance with some embodiments of the present disclosure, a top wafer may be bonded to a bottom wafer to form a composite wafer. A coefficient of thermal expansion (CTE) of the top wafer and a CTE of the bottom wafer may be different. A dopant may be implanted into the top wafer to form an implanted layer before or after the top wafer is bonded to the bottom wafer. The implanted layer may be at an intermediate level of the top wafer between a top surface and a bottom surface of the top wafer. A thinning process may be performed to reduce a thickness of the top wafer. The composite wafer is then heated, which may cause the top wafer to split into two portions at the implanted region. Afterwards, the bottom portion of the top wafer bonded to the bottom wafer may be used to form devices of the semiconductor package. Due to the thinning of the top wafer before the heating process (e.g., the wafer splitting process), warpage of the composite wafer, which may be caused by the CTE mismatch between the top wafer and the bottom wafer, during the heating process may be reduced, thereby reducing the risk of forming cracks in the composite wafer during the heating process. As a result, the yield, performance, and reliability of the semiconductor package may be improved.

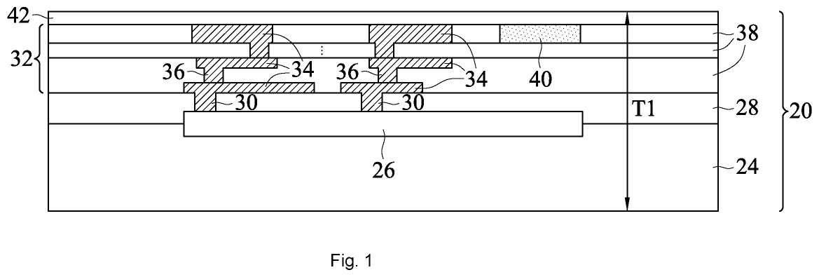

In FIG. 1, a cross-sectional view of a bottom wafer 20 is shown. The bottom wafer 20 may also be referred to as an acceptor wafer 20. In accordance with some embodiments of the present disclosure, the bottom wafer 20 is or comprises a hybrid device wafer including electronic devices and photonic devices. In accordance with some embodiments of the present disclosure, the bottom wafer 20 is or comprises an electronic device wafer including electronic devices, such as active devices and passive devices. In accordance with some embodiments of the present disclosure, the bottom wafer 20 is or comprises a photonic device wafer including photonic devices. In accordance with some embodiments of the present disclosure, the bottom wafer 20 is or comprises an interposer wafer, which includes metal features. The interposer wafer may be free of active devices, and may include passive devices. In accordance with some embodiments of the present disclosure, the bottom wafer 20 is or comprises a blank wafer, which is free from metal features, active devices, and passive devices. In accordance with some embodiments of the present disclosure, the bottom wafer 20 is or comprises a semiconductor package such as an Integrated Fan-Out (InFO) package, a system on integrated chips (SoIC) package, or a chip on wafer on substrate (CoWoS) package. The semiconductor package may include active devices encapsulated in a molding compound.

In the following discussion, the embodiments in which the bottom wafer 20 is or comprises a hybrid device wafer including electronic devices and photonic devices is used as an example. In accordance with some embodiments of the present disclosure, the bottom wafer 20 includes a semiconductor substrate 24. The semiconductor substrate 24 may be as doped or undoped silicon, an active layer of a semiconductor-on-insulator (SOI) substrate, or the like. The semiconductor substrate 24 may include other semiconductor materials, such as germanium, silicon carbide, gallium arsenic, gallium phosphide, indium phosphide, indium arsenide, indium antimonide, SiGe, GaAsP, AlInAs, AlGaAs, GaInAs, GaInP, and/or GaInAsP, or combinations thereof. Other substrates, such as multi-layered or gradient substrates, may also be used.

In accordance with some embodiments of the present disclosure, the bottom wafer 20 includes integrated circuit devices 26 (e.g., electronic devices), which are formed at a top surface of the semiconductor substrate 24. The integrated circuit devices 26 may include logic dies (e.g., central processing unit (CPU), graphics processing unit (GPU), system-on-a-chip (SoC), application processor (AP), microcontroller, etc.), memory dies (e.g., dynamic random access memory (DRAM) die, static random access memory (SRAM) die, etc.), power management dies (e.g., power management integrated circuit (PMIC) die), radio frequency (RF) dies, sensor dies, micro-electro-mechanical-system (MEMS) dies, signal processing dies (e.g., digital signal processing (DSP) die), front-end dies (e.g., analog front-end (AFE) die), the like, or combinations thereof. The details of the integrated circuit devices 26 are not illustrated herein.

In accordance with some embodiments of the present disclosure, the bottom wafer 20 includes an inter-Layer Dielectric (ILD) 28 over the semiconductor substrate 24 and fills space between the gate stacks of transistors (not shown) in the integrated circuit devices 26. The ILD 28 may be formed of or comprises Phosphosilicate Glass (PSG), Borosilicate Glass (BSG), Boron-doped Phosphosilicate Glass (BPSG), Fluorine-doped Silicate Glass (FSG), silicon oxide, silicon oxynitride, silicon nitride, or the like. ILD 28 may be formed by a suitable deposition process, such as Atomic Layer Deposition (ALD), Flowable Chemical Vapor Deposition (FCVD), Chemical Vapor Deposition (CVD), or the like. In accordance with some embodiments of the present disclosure, the bottom wafer 20 includes contact plugs 30 in the ILD 28. The contact plugs 30 may electrically connect the integrated circuit devices 26 to the overlying conductive features. The contact plugs 30 may be formed of a conductive material selected from tungsten, aluminum, copper, titanium, tantalum, titanium nitride, tantalum nitride, alloys therefore, and/or multi-layers thereof. The contact plugs 30 may be formed by a damascene process, such as a single damascene process, a dual damascene process, or the like.

In accordance with some embodiments of the present disclosure, the bottom wafer 20 includes an interconnect structure 32 over the ILD 28 and the contact plugs 30. The interconnect structure 32 may include conductive lines 34 and conductive vias 36, in dielectric layers 38, which may be also referred to as Inter-metal Dielectrics (IMDs) 38. The interconnect structure 32 may include a plurality of levels of the conductive lines 34 interconnected through the conductive vias 36. The dielectric layers 38 may be formed of low-k dielectric materials, such as dielectric materials with dielectric constants (k values) lower than about 3.5. The dielectric layers 38 may be formed by a suitable deposition process, such as ALD, FCVD, CVD, or the like. The conductive lines 34 and the conductive vias 36 may be formed of copper, a copper alloy, and/or another metal. The conductive lines 34 and the conductive vias 36 may be formed by a damascene process, such as a single damascene process, a dual damascene process, or the like. FIG. 1 shows three dielectric layers 38 in the interconnect structure 32 as an example. The interconnect structure 32 may include other numbers of the dielectric layers 38.

The interconnect structure 32 may also include a passivation layer (not shown) over the dielectric layers 38 and conductive features (not shown) in the passivation layer. The passivation layer may be formed of Undoped Silicate Glass (USG), silicon nitride, silicon oxide, or the like, or multi-layers thereof. The passivation layer may be formed by a suitable deposition process, such as ALD, FCVD, CVD, or the like. The conductive features in the passivation layer may be metal pads, such as copper pads, aluminum pads, or the like. The conductive features in the passivation layer may be formed by a damascene process, such as a single damascene process, a dual damascene process, or the like.

In accordance with some embodiments of the present disclosure, the bottom wafer 20 includes one or more photonic devices 40. The photonic device 40 may include waveguides, such as silicon waveguides and/or silicon nitride waveguides, grating couplers, photodiodes, modulators, and/or the like. In accordance with some embodiments of the present disclosure, the bottom wafer 20 may be free of photonic devices.

In accordance with some embodiments of the present disclosure, the bottom wafer 20 includes a bonding layer 42 over the interconnect structure 32. The bonding layer 42 may be used for bonding in a subsequent bonding process between the bottom wafer 20 and another wafer. A top surface of the bonding layer 42 may be planar. The bonding layer 42 may be a dielectric layer free of conductive features. In accordance with some embodiments of the present disclosure, the bonding layer 42 includes conductive features, such as bonding pads. The bonding layer 42 may be a homogeneous layer having a uniform composition. The bonding layer 42 may be formed of a silicon-base dielectric material, which may comprise one or more of oxygen, carbon, and nitrogen. For example, the bonding layer 42 may be formed of silicon oxide, silicon nitride, silicon oxynitride, silicon carbide, silicon oxycarbide, silicon carbonitride, silicon oxycarbonitride, or the like. The bonding layer 42 may be formed by a suitable deposition process, such as ALD, FCVD, CVD, or the like. The bonding layer 42 may be transparent to light.

In accordance with some embodiments of the present disclosure, the bottom wafer 20 has a thickness T1 larger than about 500 μm. In accordance with some embodiments of the present disclosure, the bottom wafer 20 has a CTE α1 in a range from about 2×10⁻⁶ °C⁻¹ to about 3×10⁻⁶ °C⁻¹, such as 2.6×10⁻⁶ °C⁻¹.

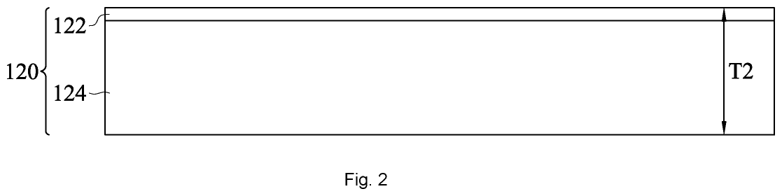

In FIG. 2, a cross-sectional view of a top wafer 120 is shown. The top wafer 120 may also be referred to as a donor wafer 120. In accordance with some embodiments of the present disclosure, the top wafer 120 is or comprises a blank wafer, which is free of metal features, active devices, and passive devices. In accordance with some embodiments of the present disclosure, the top wafer 120 is or comprises a hybrid device wafer including electronic devices and photonic devices. In accordance with some embodiments of the present disclosure, the top wafer 120 is or comprises an electronic device wafer including electronic devices, such as active devices and passive devices. In accordance with some embodiments of the present disclosure, the top wafer 120 is or comprises a photonic device wafer including photonic devices. In accordance with some embodiments of the present disclosure, the top wafer 120 is or comprises an interposer wafer, which includes metal features. The interposer wafer may be free of active devices, and may include passive devices. In accordance with some embodiments of the present disclosure, the top wafer 120 is or comprises a semiconductor package, such as an InFO package, a SoIC package, or a CoWoS package. The semiconductor package may include active devices encapsulated in a molding compound.

In the following discussion, the embodiments in which the top wafer 120 is or comprises a blank wafer is used as an example. In accordance with some embodiments of the present disclosure, the top wafer 120 includes a substrate 124. The substrate 124 may comprise a material that may be used for forming photonic devices such as waveguides, grating couplers, modulators, and/or the like, as discussed in greater details below. In accordance with some embodiments of the present disclosure, the substrate 124 has a large CTE α2 in a range from about 3×10⁻⁶ °C⁻¹ to about 50×10⁻⁶ °C⁻¹. The CTE α2 of the substrate 124 may be larger than the CTE α1 of the bottom wafer 20. As a result, there may be a CTE mismatch between the top wafer 120 and the bottom wafer 20. In accordance with some embodiments of the present disclosure, the substrate 124 comprises a semiconductor material, such as silicon, indium phosphide, gallium arsenide, or the like. In accordance with some embodiments of the present disclosure, the substrate 124 comprises a dielectric material, such as lithium niobate (LiNbO₃), lithium tantalate (LiTaO₃), or the like. In accordance with some embodiments of the present disclosure, the substrate 124 has a single crystalline structure.

In accordance with some embodiments of the present disclosure, the top wafer 120 includes a bonding layer 122 on a first surface of the substrate 124. The exposed surface of the substrate 124 may be referred to as a second surface of the substrate 124. The bonding layer 122 may be used for bonding with the bonding layer 42 of the bottom wafer 20 in a subsequent bonding process between the bottom wafer 20 and the top wafer 120. A top surface of the bonding layer 122 may be planar. The bonding layer 122 may be a dielectric layer free of conductive features. In accordance with some embodiments of the present disclosure, the bonding layer 122 includes conductive features, such as bonding pads. The bonding layer 122 may be a homogeneous layer having a uniform composition. The bonding layer 122 may be formed of a silicon-base dielectric material, which may comprise one or more of oxygen, carbon, and nitrogen. For example, the bonding layer 122 may be formed of silicon oxide, silicon nitride, silicon oxynitride, silicon carbide, silicon oxycarbide, silicon carbonitride, silicon oxycarbonitride, or the like. The bonding layer 122 may be formed by a suitable deposition process, such as ALD, FCVD, CVD, or the like. The bonding layer 122 may be transparent to light.

In accordance with some embodiments of the present disclosure, the bonding layer 122 of the top wafer 120 and the bonding layer 42 of the bottom wafer 20 comprise a same material. In accordance with some embodiments of the present disclosure, the bonding layer 122 of the top wafer 120 and the bonding layer 42 of the bottom wafer 20 comprise different materials. In accordance with some embodiments of the present disclosure, wherein the substrate 124 comprises a dielectric material, the top wafer 120 is free of the bonding layer 122 and the substrate 124 may directly bond with the bonding layer 42 in the subsequent bonding process between the bottom wafer 20 and the top wafer 120. In accordance with some embodiments of the present disclosure, the top wafer 120 has a thickness T2 larger than about 250 μm.

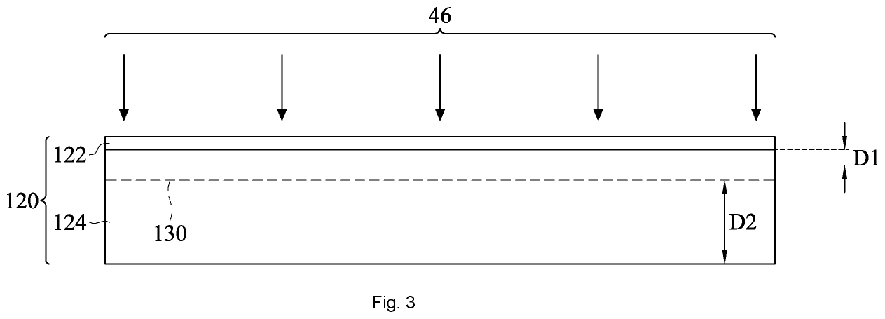

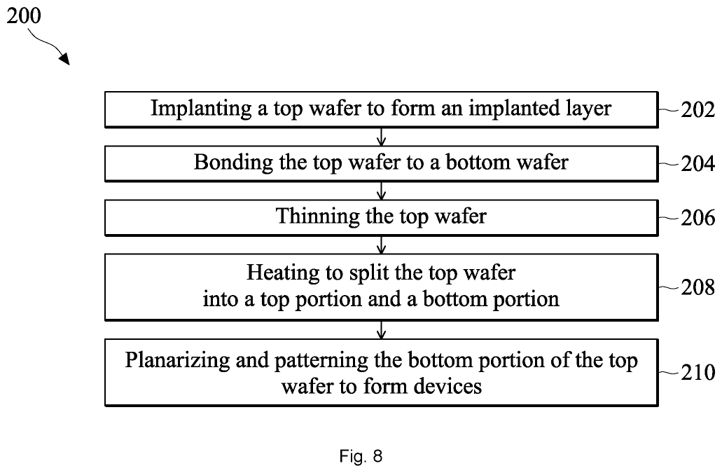

FIGS. 3, 4, 5, 6, and 7 illustrate cross-sectional views of intermediate steps of forming a semiconductor package in accordance with some embodiments of the present disclosure. The corresponding processes are also reflected schematically in the process flow shown in FIG. 8. In FIG. 3, an implantation process 46 is performed to implant a dopant into the substrate 124 to form an implanted layer 130 in accordance with some embodiments of the present disclosure. The respective process is illustrated as process 202 in the process flow 200 as shown in FIG. 8. The dopant may include ions of hydrogen, deuterium, tritium, helium, or the like. The material of the dopant may be selected based on the material of the substrate 124. For example, hydrogen may be selected when the substrate 124 comprises a semiconductor material, such as silicon gallium arsenide, indium phosphide, or the like, and helium may be selected when the substrate 124 comprises a dielectric material, such as lithium niobate, lithium tantalate, or the like.

The dopant may be implanted by a suitable implantation process, such ion implantation, or the like. The dopant ions may be implanted to be at an intermediate level of the substrate 124 between the first surface and the second surface of the substrate 124 to form the implanted layer 130. After the implantation process, the substrate 124 may comprises an implanted region (e.g., the implanted layer 130) and un-implanted regions on both sides of the implanted region. Within the implanted layer 130, the dopant ions may be substantially evenly distributed. The implanted layer 130 may be spaced apart from the first surface and the second surface of the substrate 124. The implanted layer 130 may be spaced apart from the first surface by a distance D1 smaller than about 1μm. The implanted layer 130 may be spaced apart from the second surface of the substrate 124 by a distance D2 larger than the distance D1. The implanted layer 130 may be at a location where the top wafer 120 to be split in a subsequent process as described in greater details below.

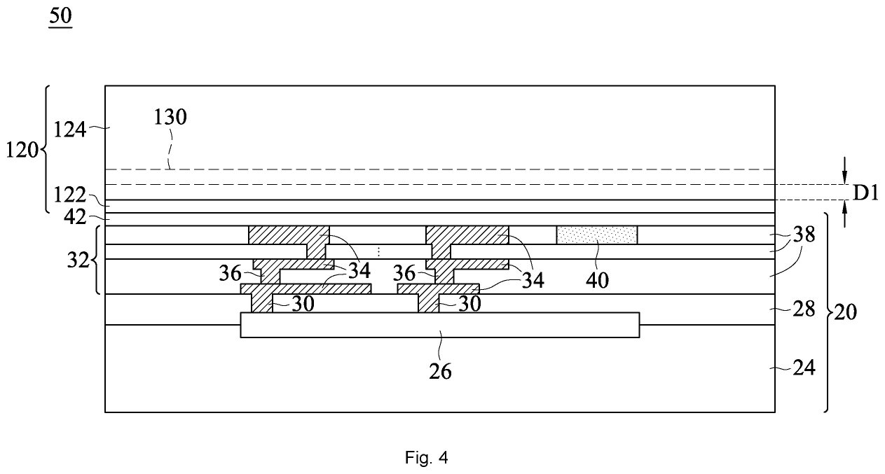

In FIG. 4, the top wafer 120 is flipped upside down, and is bonded to the bottom wafer 20 through wafer-on-wafer bonding in accordance with some embodiments of the present disclosure. The respective process is illustrated as process 204 in the process flow 200 as shown in FIG. 8. The structure if FIG. 4 may be referred to as a composite wafer 50. The wafer-on-wafer bonding process may include a surface treatment step, a pressing step, and an annealing step. During the surface treatment step, surfaces of the bonding layer 122 and the bonding layer 42 may be cleaned by solvents and treated by oxygen plasma or the like. Then, the top wafer 120 may be flipped upside down and placed on the bottom wafer 20. A small pressing force may be applied to press the top wafer 120 against the bottom wafer 20 during the pressing step at a low temperature, such as room temperature. A center point of the top wafer 120 may be initially placed into contact with a center point of the bottom wafer 20, and as the pressing step continues, the contact between the top wafer 120 and the bottom wafer 20 may propagate from the centers of the top wafer 120 and the bottom wafer 20 to the entirety of the top wafer 120 and the bottom wafer 20. After the pressing step, dielectric-to-dielectric bonds may be formed between the bonding layer 122 and the bonding layer 42. The bonding strength between the bonding layer 122 and the bonding layer 42 may be improved in the subsequent annealing step at a higher temperature, such a temperature in a range from about 100 °C to about 150 °C.

In accordance with the embodiments where the substrate 124 comprises a dielectric material, the top wafer 120 is free of the bonding layer 122, the substrate 124 of the top wafer 120 may be bonded with the bonding layer 42 directly to form dielectric-to-dielectric bonds. The bonding process between the substrate 124 and the bonding layer 42 may include the surface treatment step, the pressing step, and the annealing step similar to the bonding process between the bonding layer 122 and the bonding layer 4 described above. FIGS. 3 and 4 illustrate a sequence where the implantation process 46 is performed to form the implanted layer 130 in the top wafer 120 before the top wafer 120 is bonded to the bottom wafer 20 as an example. In accordance with some embodiments of the present disclosure, the top wafer 120 is bonded to the bottom wafer 20 before the implantation process 46 is performed to form the implanted layer 130 in the top wafer 120.

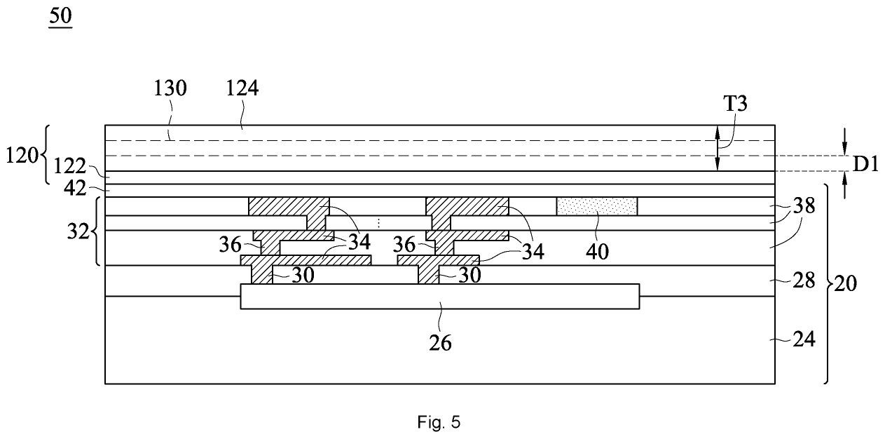

In FIG. 5, the top wafer 120 is thinned in accordance with some embodiments of the present disclosure. The respective process is illustrated as process 206 in the process flow 200 as shown in FIG. 8. The top wafer 120 may be thinned by a mechanical thinning process, such as grinding or the like, a chemical thinning process, such as dry etching, wet etching, or the like, or a chemical mechanical thinning process, such as CMP or the like. The thinning process may partially remove the exposed un-implanted region of the substrate 124, while keeping implanted region (e.g., the implanted layer 130) intact. After the thinning process, the substrate 124 may have a thickness T3 smaller than about 100 μm. Since there may be a CTE mismatch between the top wafer 120 and the bottom wafer 20 due the large CTE α2 of the substrate 124 as described with respect to FIG. 2, the composite wafer 50 may experience substantial warpage when the composite wafer 50 is heated. Thinning the substrate 124 to the thickness T3 (smaller than about 100 μm) may lead to reduced warpage of the composite wafer 50 during a subsequent process, thereby reducing the risk of forming cracks in the composite wafer 50 during subsequent process as described in greater details below.

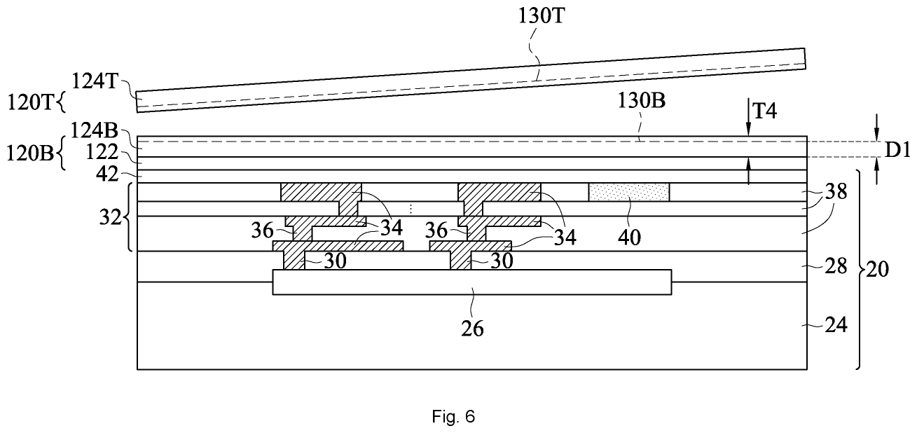

In FIG. 6, the composite wafer 50 is heated and the top wafer 120 is split into a top portion 120T and a bottom portion 120B in accordance with some embodiments of the present disclosure. The respective process is illustrated as process 208 in the process flow 200 as shown in FIG. 8. The splitting of the composite wafer 50 may take place at the implanted layer 130 of the substrate 124 and the implanted layer 130 may be split into a top portion 130T and a bottom portion 130B. After the composite wafer 50 is split, the top portion 120T of the top wafer 120 may be a top portion 124T of the substrate 124 comprising the top portion 130T of the implanted layer 130, and the bottom portion 120B of the top wafer 120 may comprise a bottom portion 124B of the substrate 124 comprising the bottom portion 130B of the implanted layer 130 and the bonding layer 122. The top portion 120T of the top wafer 120 may be removed and the bottom portion 120B of the top wafer 120 may remain bonded to the bottom wafer 20 and may be used to form devices in a subsequent process. The un-implanted region of the bottom portion 120B of the top wafer 120 may be intact after the composite wafer 50 is split. The bottom portion 124B of the substrate 124 may have a thickness T4 smaller than about 1 μm.

During the heating process, the composite wafer 50 may be heated at a temperature in a range from about 200 °C to about 300 °C for a duration in a range from about 0.5 hours to about 10 hours. The temperature and duration of heating process may depend on the material of the substrate 124, and the material and the concentration of the dopant ions in the implanted layer 130. The composite wafer 50 may be heated by a heating unit (e.g., hotplate) from the bottom, a heating unit (e.g., heat lamp) from the top, or a heating unit (e.g., oven) from the surrounding. The heating process may be performed in an inert environment, such as in a nitrogen environment, argon environment, or the like. The heating process may be also referred to as a split annealing process. During the heating process, the dopant ions in the implanted layer 130 may form gas, such as hydrogen gas, helium gas, or the like, which may expand and split the composite wafer 50 at the implanted layer 130 of the substrate 124. Due to the thinning of the substrate 124 to the thickness T3 (smaller than about 100 μm) before the heating process, the warpage of the composite wafer 50 during the heating process may be reduced, which may reduce the risk of forming cracks in the composite wafer 50 during the heating process. As a result, the yield, performance, and reliability of the subsequently formed semiconductor package may be improved.

The process described with respect to FIGS. 3 through 6, where the top wafer 120 is implanted with dopant ions and split into two portions by heating, may be referred to as an ion cut process of the top wafer 120. The ion cut process may allow for obtaining a wafer with a small thickness, such as smaller than about 1 μm, by splitting the wafer. Obtaining the wafer such a small thickness may not be feasible by conventional thinning processes, such as grinding, CMP, or the like.

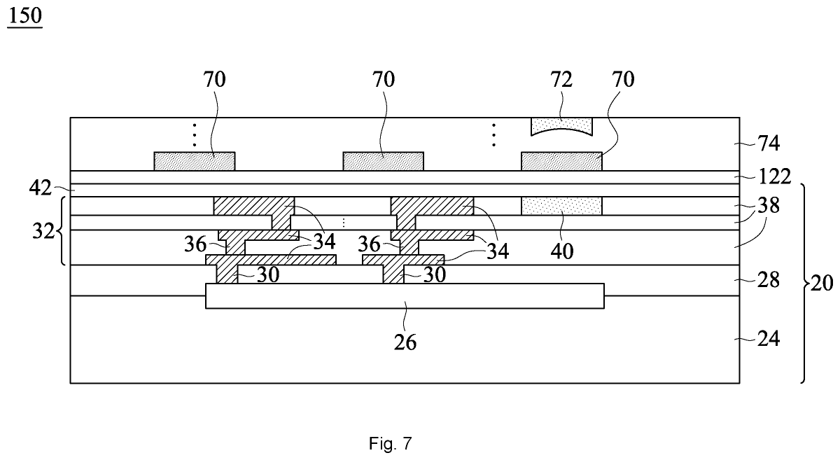

FIG. 7 shows a semiconductor package 150 formed based on the structure shown in FIG. 6 by performing various additional processes, including forming photonic devices 70 using the bottom portion 120B of the top wafer 120 in accordance with some embodiments of the present disclosure. The respective process is illustrated as process 210 in the process flow 200 as shown in FIG. 8. The bottom portion 120B of the top wafer 120 in may be first planarized to form a planar top surface. The planarization process may comprise grinding, CMP, or the like. In accordance with some embodiments of the present disclosure, the implanted region of the bottom portion 124B of the substrate 124 is removed during the planarization processes. The bottom portion 120B of the top wafer 120 may then be patterned to form the photonic devices 70 by a suitable photolithography process. The photonic devices 70 may comprise the material of the substrate 124, such as silicon, indium phosphide, gallium arsenide, lithium niobate (LiNbO₃), lithium tantalate (LiTaO₃), or the like. The photonic devices 70 may include waveguides, grating couplers, photodiodes, modulators, and/or the like. The photonic devices 70 may be optically connected to the photonic device 40 of the bottom wafer 20. In accordance with some embodiments of the present disclosure, the photonic devices 70 are free of the dopant used to implant the substrate 124.

Additional features may be formed over the photonic devices 70 in accordance with some embodiments of the present disclosure. The additional features may include a plurality of dielectric layers 74, which may be transparent to light, additional waveguides (not shown) in the dielectric layers 74, such as nitride waveguides, and micro-lens 72 in the dielectric layers 74 with an exposed top surface. The additional waveguides may optically connect the photonic devices 70 and the micro-lens 72.

The embodiments of the present disclosure have some advantageous features. By thinning of the substrate 124 to the thickness T3 before the heating process (e.g., split annealing process), the warpage of the composite wafer 50, which may be caused by the CTE mismatch between the top wafer 120 and the bottom wafer 20, during the heating process may be reduced, thereby reducing the risk of forming cracks in the composite wafer 50 during the heating process. As a result, the yield, performance, and reliability of the semiconductor package 150 may be improved.

In an embodiment, a method includes implanting a substrate with a dopant to form an implanted layer in the substrate; thinning the substrate; and heating the substrate to split the substrate at the implanted layer, wherein the substrate is split into a first portion and a second portion. In an embodiment, thinning the substrate is done by etching, grinding, or chemical mechanical polishing (CMP). In an embodiment, method of further includes bonding the substrate to a wafer by bonding a first bonding layer on the substrate to a second bonding layer on the wafer before thinning the substrate. In an embodiment, the first portion of the substrate remains bonded to the wafer after heating the substrate, and wherein a thickness of the first portion of the substrate is smaller than 1 μm. In an embodiment, the substrate has a higher coefficient of thermal expansion (CTE) than the wafer. In an embodiment, the substrate has a single crystalline structure. In an embodiment, the substrate includes a dielectric material. In an embodiment, the substrate includes a semiconductor material.

In an embodiment, a method includes implanting a substrate with a dopant to form an implanted layer in the substrate; bonding the substrate to a wafer with integrated circuit devices; thinning the substrate; and heating the substrate to split the substrate at the implanted layer, wherein the substrate is split into a first portion and a second portion, and wherein the first portion of the substrate remains bonded to the wafer after heating the substrate. In an embodiment, the first portion of the substrate includes an implanted region and an un-implanted region. In an embodiment, the dopant is hydrogen or helium. In an embodiment, the method further includes planarizing the first portion of the substrate after heating the substrate. In an embodiment, the method further includes patterning the first portion of the substrate to form photonic devices after the first portion of the substrate is planarized.

In an embodiment, a method includes implanting a substrate with a dopant to form an implanted layer in the substrate, wherein the implanted layer is spaced apart from a first surface and a second surface of the substrate, and wherein the implanted layer is closer to the first surface of the substrate than the second surface of the substrate; bonding the substrate to a wafer, wherein the first surface of the substrate faces the wafer; thinning the substrate at the second surface; and heating the substrate to split the substrate at the implanted layer, wherein the substrate is split into a first portion and a second portion. In an embodiment, the substrate has a higher coefficient of thermal expansion (CTE) than the wafer. In an embodiment, heating the substrate is performed at a temperature higher than 200 °C. In an embodiment, the substrate has a thickness less than 100 μm after thinning the substrate. In an embodiment, the substrate is bonded to the wafer by dielectric-to-dielectric bonding. In an embodiment, the substrate includes silicon, gallium arsenide, or indium phosphide. In an embodiment, the substrate includes lithium niobate or lithium tantalate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
implanting a dopant into a substrate to form an implanted layer in the substrate, the implanted layer being at an intermediate level of the substrate between a first surface and a second surface of the substrate, the implanted layer being closer to the first surface than to the second surface;
bonding the first surface of the substrate to a wafer, the substrate having a higher coefficient of thermal expansion than the wafer;
after the bonding, thinning the substrate from the second surface; and
after the thinning, heating the substrate to split the substrate into a first portion and a second portion at the implanted layer, the first portion remaining bonded to the wafer.

2. The method of claim 1, wherein thinning the substrate comprises etching, grinding, or chemical mechanical polishing.

3. The method of claim 1, wherein bonding the substrate to the wafer comprises bonding a first bonding layer on the substrate to a second bonding layer on the wafer.

4. The method of claim 1, wherein the substrate is bonded to the wafer by dielectric-to-dielectric bonding.

5. The method of claim 1, wherein the coefficient of thermal expansion of the substrate is in a range from 3×10⁻⁶ °C⁻¹ to 50×10⁻⁶ °C⁻¹.

6. The method of claim 1, wherein heating the substrate comprises heating the substrate at a temperature in a range from 200 °C to 300 °C for a duration in a range from 0.5 hours to 10 hours.

7. The method of claim 1, wherein the dopant comprises hydrogen or helium.

8. The method of claim 1, wherein the first portion comprises an implanted region and an un-implanted region.

9. A method comprising:
implanting a dopant into a substrate to form an implanted layer in the substrate, the implanted layer being closer to a first surface of the substrate facing a wafer than to a second surface of the substrate opposite the first surface, and the implanted layer being spaced apart from the first surface by a distance less than 1 μm;
bonding the first surface of the substrate to the wafer, the substrate having a higher coefficient of thermal expansion than the wafer;
after the bonding, thinning the substrate to a thickness less than 100 μm; and
after the thinning, heating the substrate to a temperature in a range from 200 °C to 300 °C to split the substrate into a first portion and a second portion at the implanted layer, wherein the first portion remains bonded to the wafer and has a thickness less than 1 μm.

10. The method of claim 9, wherein thinning the substrate comprises grinding, etching, or chemical mechanical polishing.

11. The method of claim 9, wherein the substrate has a single crystalline structure.

12. The method of claim 9, wherein the substrate comprises silicon, gallium arsenide, or indium phosphide.

13. The method of claim 9, wherein the substrate comprises lithium niobate or lithium tantalate.

14. The method of claim 9, wherein the dopant comprises hydrogen or helium.

15. The method of claim 9, wherein the first portion comprises an implanted region and an un-implanted region.

16. A method comprising:
implanting a dopant into a substrate of a top wafer to form an implanted layer in the substrate;
bonding the top wafer to a bottom wafer by dielectric-to-dielectric bonding, the bottom wafer comprising a first photonic device, the substrate having a higher coefficient of thermal expansion than the bottom wafer;
after the bonding, thinning the substrate;
after the thinning, heating the substrate to split the substrate into a first portion and a second portion at the implanted layer, wherein the first portion remains bonded to the bottom wafer;
planarizing the first portion;
patterning the first portion to form a second photonic device optically connected to the first photonic device; and
forming a plurality of dielectric layers transparent to light over the second photonic device, the dielectric layers comprising a micro-lens having an exposed top surface.

17. The method of claim 16, wherein the second photonic device comprises a waveguide, a grating coupler, a photodiode, or a modulator.

18. The method of claim 16, wherein the second photonic device is free of the dopant.

19. The method of claim 16, wherein thinning the substrate comprises thinning the substrate to a thickness less than 100 μm.

20. The method of claim 16, further comprising forming a waveguide in the dielectric layers, the waveguide optically connecting the second photonic device and the micro-lens.
